(19) United States
(12) Patent Application Publication
(10) Pub. No.: US 2008/0050898 A1
(43) Pub. Date: Feb. 28, 2008

(54) Semiconductor devices and methods of manufacture thereof

(76) Inventor: Hongfa Luan, Austin, TX (US)

Correspondence Address: SLATER & MATSIL, L.L.P., 17950 PRESTON ROAD, SUITE 1000, DALLAS, TX, 75252, US

(21) Appl. No.: 11/508,682

(22) Filed: Aug. 23, 2006

(51) Int. Cl. H01L 21/3205

(52) U.S. Cl. 438/585

(57) ABSTRACT

Semiconductor devices and methods of manufacture thereof are disclosed. In a preferred embodiment, a method of manufacturing a semiconductor device includes providing a workpiece, disposing a gate dielectric material over the workpiece, and disposing a gate material over the gate dielectric material. Cl or F is introduced to the gate material, wherein introducing the Cl or F to the gate material affects a work function of the gate material. The gate material and the gate dielectric material are patterned, forming at least one transistor.

### TECHNICAL FIELD

The present invention relates generally to the fabrication of semiconductor devices, and more particularly to transistors and methods of manufacture thereof.

### BACKGROUND

Semiconductor devices are used in a variety of electronic applications, such as personal computers, cell phones, digital cameras, and other electronic equipment, as examples. Semiconductor devices are typically fabricated by sequentially depositing insulating or dielectric layers, conductive layers, and semiconductive layers of material over a semiconductor substrate, and patterning the various layers using lithography to form circuit components and elements thereon.

A transistor is an element that is utilized extensively in semiconductor devices. There may be millions of transistors on a single integrated circuit (IC), for example. A common type of transistor used in semiconductor device fabrication is a metal oxide semiconductor field effect transistor (MOSFET).

Early MOSFET processes used one type of doping to create single transistors that comprised either positive or negative channel transistors. Other more recent designs, referred to as complementary MOS (CMOS) devices, use both positive and negative channel devices, e.g., a positive channel metal oxide semiconductor (PMOS) transistor and a negative channel metal oxide semiconductor (NMOS) transistor, in complementary configurations. An NMOS device negatively charges so that the transistor is turned on or off by the movement of electrons, whereas a PMOS device involves the movement of electron vacancies. While the manufacturing of CMOS devices requires more manufacturing steps and more transistors, CMOS devices are advantageous because they utilize less power, and the devices may be made smaller and faster.

The gate dielectric for MOSFET devices has in the past typically comprised silicon dioxide, which has a dielectric constant of about 3.9. However, as devices are scaled down in size, using silicon dioxide for a gate dielectric material becomes a problem because of gate leakage current, which can degrade device performance. Therefore, there is a trend in the industry towards the development of the use of high dielectric constant (k) materials for use as the gate dielectric material in MOSFET devices. The term “high k dielectric materials” as used herein refers to dielectric materials having a dielectric constant of about 4.0 or greater, for example.

High k gate dielectric material development has been identified as one of the future challenges in the 2002 edition of International Technology Roadmap for Semiconductors (ITRS), which is incorporated herein by reference, which identifies the technological challenges and needs facing the semiconductor industry over the next 15 years. For low power logic (for portable electronic applications, for example), it is important to use devices having low leakage current, in order to extend battery life. Gate leakage current must be controlled in low power applications, as well as sub-threshold leakage, junction leakage, and band-to-band tunneling.

In electronics, the “work function” is the energy, usually measured in electron volts, needed to remove an electron from the Fermi level to a point an infinite distance away outside the surface. Work function is a material property of any material, whether the material is a conductor, semiconductor, or dielectric.

The work function of a semiconductor material can be changed by doping the semiconductor material. For example, undoped polysilicon has a work function of about 4.65 eV, whereas polysilicon doped with boron has a work function of about 5.15 eV. When used as a gate electrode, the work function of a semiconductor or conductor directly affects the threshold voltage of a transistor, for example.

In prior art CMOS devices utilizing SiO₂ as the gate dielectric material and polysilicon as the gate electrode, the work function of the polysilicon could be changed or tuned by doping the polysilicon (e.g., implanting the polysilicon with dopants). However, high k gate dielectric materials such as hafnium-based dielectric materials exhibit a Fermi-pinning effect, which is caused by the interaction of the high k gate dielectric material with the adjacent gate material. When used as a gate dielectric, some types of high k gate dielectric materials can pin or fix the work function, so that doping the polysilicon gate material does not change the work function. Thus, a symmetric Vₜ for the NMOS and PMOS transistors of a CMOS device having a high k dielectric material for the gate dielectric cannot be achieved by doping the polysilicon gate material, as in SiO₂ gate dielectric CMOS devices.

The Fermi-pinning effect of high k gate dielectric materials causes a threshold voltage shift and low mobility, due to the increased charge caused by the Fermi-pinning effect. Fermi-pinning of a high k gate dielectric material causes an asymmetric turn-on threshold voltage Vₜ for the transistors of a CMOS device, which is undesirable. Efforts have been made to improve the quality of high k dielectric films and resolve the Fermi-pinning problems, but the efforts have resulted in little success.

Metal would be preferred over polysilicon as a gate material, to avoid a gate depletion effect and reduce the equivalent oxide thickness (EOT) of the gate dielectric.

Thus, what are needed in the art are metal gate electrodes that have a suitable work function for CMOS device designs.

### SUMMARY OF THE INVENTION

These and other problems are generally solved or circumvented, and technical advantages are generally achieved, by preferred embodiments of the present invention, which comprise novel structures and methods of forming semiconductor devices.

In accordance with a preferred embodiment of the present invention, a method of manufacturing a semiconductor device includes providing a workpiece, disposing a gate dielectric material over the workpiece, and disposing a gate material over the gate dielectric material. Cl or F is introduced to the gate material, wherein introducing the Cl or F to the gate material affects a work function of the gate material. The gate material and the gate dielectric material are patterned, forming at least one transistor.

The foregoing has outlined rather broadly the features and technical advantages of embodiments of the present invention in order that the detailed description of the invention that follows may be better understood. Additional features and advantages of embodiments of the invention will be described hereinafter, which form the subject of the claims of the invention. It should be appreciated by those skilled in the art that the conception and specific embodiments disclosed may be readily utilized as a basis for modifying or designing other structures, such as capacitors or gated diodes, as examples, or other processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention and the advantages thereof, reference is now made to the following descriptions taken in conjunction with the accompanying drawings, in which:

FIGS. 1 through 6 show cross-sectional views of a semiconductor device at various stages of manufacturing in accordance with an embodiment of the present invention, wherein a CMOS device comprises a PMOS transistor and an NMOS transistor having different gate materials;

FIGS. 7 through 10 show cross-sectional views of another method of manufacturing a CMOS device in accordance with an embodiment of the present invention, wherein a cap layer is formed over the gate material of the PMOS transistor, but not the NMOS transistor;

FIGS. 11 through 15 are graphs illustrating experimental test results of flat band voltage versus effective oxide thickness (EOT) at various test conditions and device configurations in accordance with embodiments of the present invention;

FIG. 16 shows a cross-sectional view of a semiconductor device in accordance with another preferred embodiment of the present invention, implemented in a FinFET device; and

FIG. 17 shows a cross-sectional view an embodiment of the present invention implemented in a multiple-gate device.

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

When used as a gate dielectric of a transistor, high k gate dielectric materials have generally shown to yield orders of magnitude lower gate leakage current than SiO₂ gate dielectric materials having the same effective oxide thickness (EOT). For low standby power (LSTP) and high performance (HP) applications, a high k gate dielectric material is a potential solution in the roadmap for advanced technology nodes. High k gate dielectric materials are expected to achieve the EOT, gate leakage (J_{g}), mobility, and hysteresis parameters required by LSTP applications.

However, threshold voltage Vₜ controllability with high k gate dielectric materials is proving challenging. For example, in order for high k gate dielectric materials to be useful in CMOS applications, a CMOS device requires a symmetrical Vₜₙ and Vₜₚ (e.g., Vₜₙ=+0.3 V and Vₜₚ=−0.3 V).

Attempts to use high k dielectric materials as a gate dielectric material have been problematic. In particular, attempts have been made to use HfO₂, which is a high k dielectric material having a dielectric constant of about 25, as a gate dielectric for the PMOS and NMOS FETs of a CMOS device. However, the use of polysilicon as a gate material is incompatible with Hf-based high k dielectric materials in CMOS applications. If polysilicon is used as a gate material, the work function of the polysilicon gate using an HfO₂ gate dielectric has been found to be pinned as a result of Fermi-pinning, at a point close to the conduction band of polysilicon, causing the polysilicon gate to function as N type polysilicon, even for a polysilicon gate doped with P type dopant, for the PMOS device. This has been found to cause asymmetric threshold voltages Vₜ for the PMOS and NMOS transistors of CMOS devices. Polysilicon used as a material for a gate electrode will also cause a poly depletion problem, for example.

Because the Fermi-pinning effect makes polysilicon incompatible for use as a gate material (e.g., used directly adjacent the gate dielectric), it is desirable to find metals that may be used for PMOS and NMOS devices as a gate material.

For classical bulk MOSFET devices, it is expected that conventional high performance CMOS devices will require the use of both high k dielectric materials as gate dielectrics and metals as gate electrodes in order to eliminate poly depletion and the Fermi-pinning effect, as devices scale down to the 1 nm equivalent oxide thickness (EOT) (e.g., for the gate material). Potential metal gate materials must exhibit band-edge work functions, exhibit work function stability as a function of temperature, and maintain thermal stability with the underlying dielectric, as examples. The semiconductor industry is struggling to find adequate n-type and p-type metal materials to use as gate electrodes for the conventional bulk MOSFET. It is desirable to find metals wherein the work function is about 4.1 eV for an n-type transistor (NMOS) and about 5.2 eV for a p-type transistor (PMOS), as examples.

Next, some definitions of terms used herein will next be described. The term, “mid-gap gate work function” is defined herein to be around 4.65 eV, because this is the “mid” or middle value of the work functions of n-doped polycrystalline silicon with a work function of approximately 4.1 eV, and p-doped poly-crystalline silicon having a work function of approximately 5.2 eV, as examples. The difference between 4.1 eV and 5.2 eV is the energy gap of 1.1 eV between the valence band and the conduction band of silicon, for example.

The present invention will next be described with respect to preferred embodiments in a specific context, namely implemented as a p-type gate electrode in CMOS devices and CMOS device integration with comprising transistors having single and multiple gates. Embodiments of the present invention may also be applied, however, to other semiconductor device applications where one or more transistor is utilized, as examples. Note that in the drawings shown, only one CMOS device is shown; however, there may be many transistors formed on a semiconductor workpiece during each of the manufacturing processes described herein. The term “gate” and “gate electrode” refer to the gate of a transistor, and these terms are used interchangeably herein.

Embodiments of the present invention provide a novel p-type gate electrode and dual metal gate electrode/high-k gate dielectric solution for CMOS transistor applications. In some embodiments, a p-type gate electrode material is disclosed, e.g., for a PMOS transistor. In other embodiments, one transistor of a CMOS device, e.g., a PMOS transistor, comprises a gate material containing a substance that the other transistor e.g., an NMOS transistor does not contain, altering properties of the gate material of the PMOS device, to be described further herein.

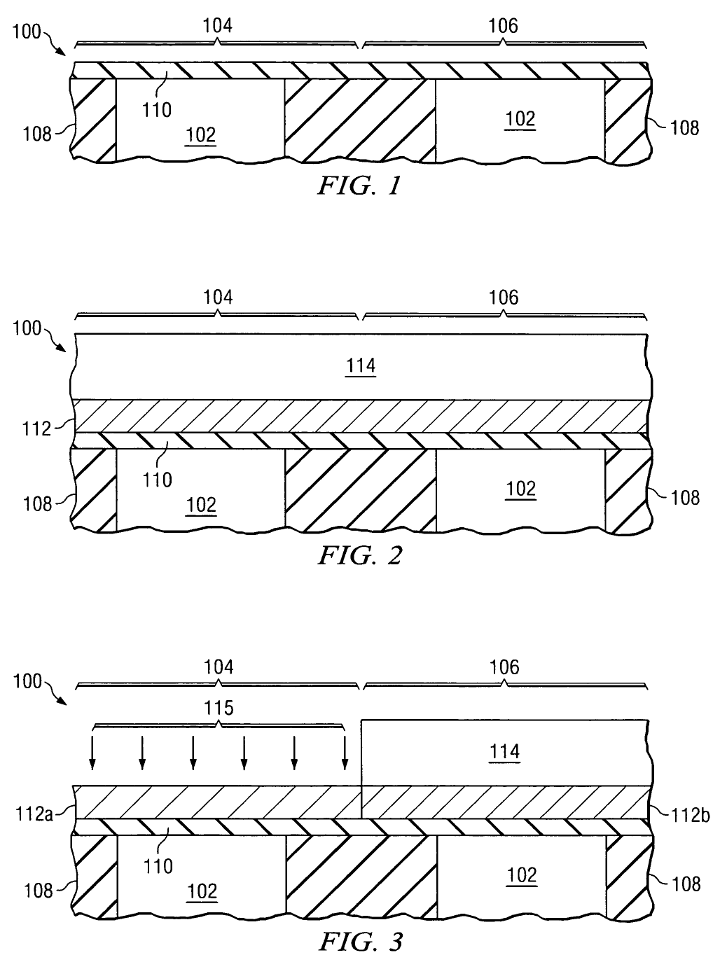

FIGS. 1 through 6 show cross-sectional views of a semiconductor device 100 at various stages of manufacturing in accordance with a preferred embodiment of the present invention. In the embodiment shown in FIGS. 1 through 6, a semiconductor device 100 is shown comprising a CMOS device that includes a PMOS transistor 120 and an NMOS transistor 122, e.g., as shown in FIG. 6. However, with reference to region 104 of the workpiece 102, a novel PMOS transistor 120 and method of manufacture thereof will first be generally described.

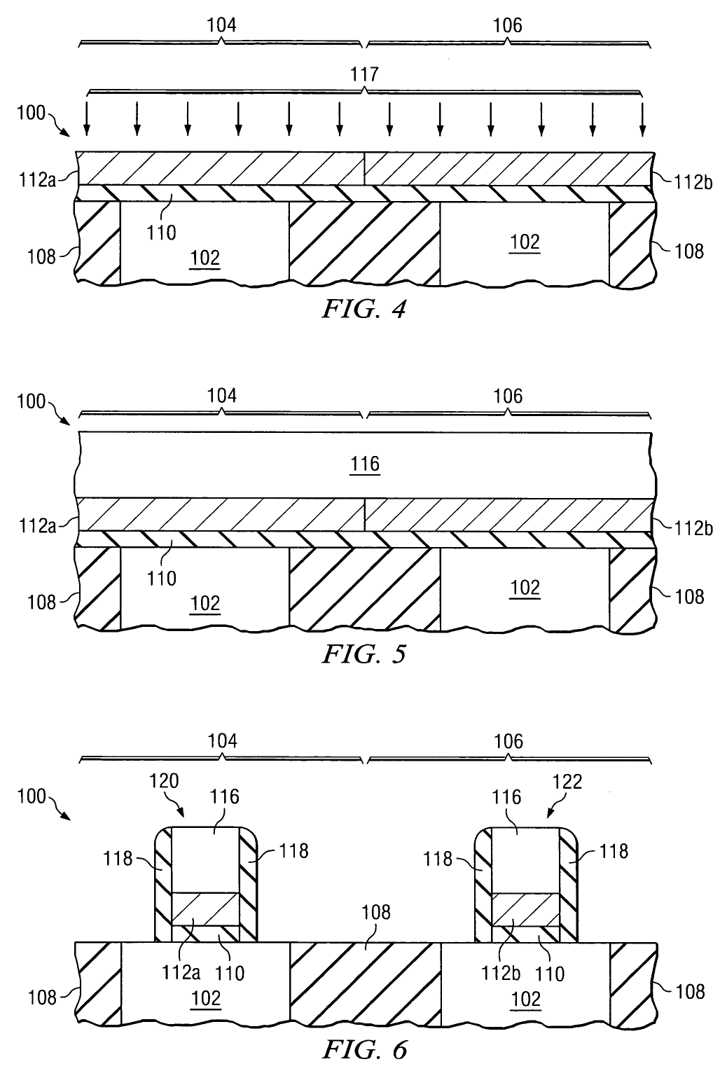

For example, in accordance with an embodiment of the invention, a method of manufacturing a semiconductor device 100 includes providing a workpiece 102, as shown in FIG. 1 in first region 104 of the workpiece 102, disposing a gate dielectric material 110 over the workpiece 102, and disposing a gate material 112 over the gate dielectric material 110, as shown in FIG. 2. The gate material 112 preferably comprises HfSi. A substance 115 comprising Cl or F is introduced to the gate material 112, as shown in FIG. 3, forming a gate material 112a that includes the Cl or F (e.g., substance 115), wherein introducing the Cl or F to the gate material affects a work function of the gate material 112a. The workpiece 102 is preferably annealed using an anneal process 117, as shown in FIG. 4. The gate material 112a and the gate dielectric material 110 are patterned, forming at least one transistor 120, as shown in FIG. 6.

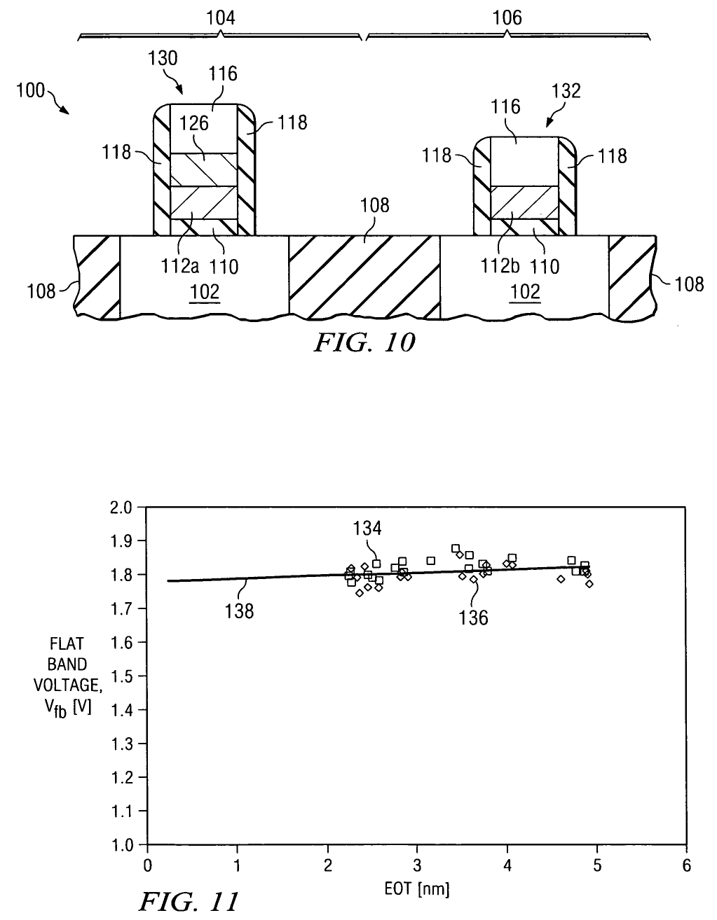

The transistor 120 in region 104 preferably comprises a PMOS transistor, in some embodiments, for example. The PMOS transistor 120 may include a layer of semiconductive material 116 formed over the gate material 112a and an optional cap layer 126 disposed between the semiconductive material 116 and the gate material 112a, as shown in FIG. 10. Advantageously, the gate material 112a comprising HfSiCl or HfSiF has a work function of about 5.2 to 5.9, to be described further herein.

Embodiments of the present invention also include novel CMOS devices that include the PMOS transistor 120 and an NMOS transistor 122 comprising a different gate material 112b than the gate material 112a of the PMOS transistor 120, as shown in FIG. 6. A more detailed description of a method of manufacturing a CMOS device in accordance with a preferred embodiment of the present invention will next be described. Similar materials, dimensions, and methods may be used to manufacture a single PMOS transistor 120, for example.

With reference now to FIG. 1, there is shown a semiconductor device 100 in a cross-sectional view including a workpiece 102. The workpiece 102 may include a semiconductor substrate comprising silicon or other semiconductive materials covered by an insulating layer, for example. The workpiece 102 may also include other active components or circuits, not shown. The workpiece 102 may comprise silicon oxide over single-crystal silicon, for example. The workpiece 102 may include other conductive layers or other semiconductor elements, e.g., transistors, diodes, etc. Compound semiconductors, GaAs, InP, Si/Ge, or SiC, as examples, may be used in place of silicon. In one embodiment, the workpiece 102 preferably comprises a silicon-on-insulator (SOI) substrate, including a first layer of semiconductive material (not shown), a buried insulating layer or buried oxide layer (also not shown) disposed over the first layer of semiconductive material, and a second layer of semiconductive material disposed over the buried insulating layer, for example.

The workpiece 102 may be doped with P type dopants and N type dopants, e.g., to form a P well and N well, respectively (not shown). For example, a PMOS device is typically implanted with N type dopants, e.g., in a first region 104, and an NMOS device is typically implanted with P type dopants, e.g., in a second region 106. The workpiece 102 may be cleaned using a pre-gate cleaning process to remove contaminants or native oxide from the top surface of the workpiece 102. The pre-gate treatment may comprise an HF, HCl, or an ozone based cleaning treatment, as examples, although the pre-gate treatment may alternatively comprise other chemistries.

Shallow trench isolation (STI) regions 108 may be formed between what will be active areas in the first and second regions 104 and 106 of the workpiece 102. If the workpiece 102 comprises an SOI substrate 102, the shallow trench isolation region 108 may be formed by patterning the second layer of semiconductive material of the workpiece 102, and filling the patterned second layer of semiconductive material with an insulating material such as silicon dioxide, although other materials may be used, for example. The STI region 108 may be formed in the second layer of semiconductive material of the workpiece, and the etch process for the STI region 108 trenches may be adapted to stop on the buried insulating layer of the SOI substrate 102, for example.

A gate dielectric material 110 is formed over the workpiece 102. The gate dielectric material 110 preferably comprises a high k dielectric material having a dielectric constant of about 4.0 or greater, in one embodiment, for example. The gate dielectric material 110 may alternatively comprise a dielectric material such as SiO₂, for example. The gate dielectric material 110 preferably comprises HfO₂, HfSiOx, Al₂O₃, ZrO₂, ZrSiOx, Ta₂O₅, La₂O₃, nitrides thereof, SiₓN_{y}, SiON, HfAlOₓ, HfAlOₓN_{1-x-y}, ZrAlOₓ, ZrAlOₓN_{y}, SiAlOₓ, SiAlOₓN_{1-x-y}, HfSiAlOₓ, HfSiAlOₓN_{y}, ZrSiAlOₓ, ZrSiAlOₓN_{y}) SiO₂, combinations thereof, or multiple layers thereof, as examples, although alternatively, the gate dielectric material 110 may comprise other high k dielectric materials or other dielectric materials.

The gate dielectric material 110 may comprise a single layer of material, or alternatively, the gate dielectric material 110 may comprise two or more layers. In one embodiment, one or more of these materials can be included in the gate dielectric material 110 in different combinations or in stacked layers. The gate dielectric material 110 may be formed by chemical vapor deposition (CVD), atomic layer deposition (ALD), metal organic chemical vapor deposition (MOCVD), physical vapor deposition (PVD), or jet vapor deposition (JVD), as examples, although alternatively, the gate dielectric material 110 may be formed using other techniques.

The gate dielectric material 110 preferably comprises a thickness of about 100 Angstroms or less in one embodiment, although alternatively, the gate dielectric material 110 may comprise other dimensions. The gate dielectric material 110 preferably comprises about 20 to 30 Angstroms, in one embodiment, for example. In one embodiment, the gate dielectric material 110 preferably comprises about 20 Angstroms of HfSiO₂. Alternatively, the gate dielectric material 110 may comprise other materials, combinations of materials, and thicknesses, as examples.

Next, a gate material 112 is formed over the gate dielectric material 110, as shown in FIG. 2. The gate material 112 preferably comprises a layer of HfSi, in accordance with some embodiments of the present invention. The gate material 112 alternatively may comprise other metals in which the work function of the metal may be adjusted, tuned, or altered by exposing the metal to a substance such as Cl or F, for example. The gate material 112 is preferably deposited using MOCVD in one embodiment, using a Hf precursor and a Si precursor, as an example. The gate material 112 may include some amount of oxygen, carbon, nitrogen or other materials from the chemical precursor used to deposit the gate material 112, for example. Alternatively, the gate material 112 may be formed by ALD, PVD, or other deposition techniques, as examples. The gate material 112 preferably comprises a thickness of about 200 Angstroms or less, and more preferably comprises a thickness of about 50 to 100 Angstroms in some embodiments, as examples, although alternatively, the thickness of the gate material 112 may comprise other dimensions. The gate material 112 as deposited preferably comprises the same material and thickness over the first region 104 and the second region 106 of the workpiece 102, for example.

Next, a layer of photoresist 114 is deposited over the gate material 112, as shown in FIG. 2. The layer of photoresist 114 is patterned using lithography techniques to remove the layer of photoresist 114 from over the first region 104 of the workpiece 102. For example, the layer of photoresist 114 may be patterned by exposing the layer of photoresist 114 to energy through a mask (not shown), and then portions of the layer of photoresist 114 are developed, leaving the patterned layer of photoresist 114 shown in FIG. 3.

A substance 115 comprising chlorine (Cl) or fluorine (F) is introduced to the gate material 112 in the first region 104 of the workpiece 102, as shown in FIG. 3. Introducing the substance 115 preferably comprises a treatment of the gate material 112 in the first region 104 of the workpiece 102 using Cl plasma in one embodiment. In another embodiment, introducing the substance 115 preferably comprises implanting Cl or F into the gate material 112 in the first region 104 of the workpiece 102. The implantation step may comprise implanting Cl or F ions into the gate material 112 in the first region 104 of the workpiece 102, as an example. Alternatively, introducing the substance 115 may comprise a treatment using Cl or F plasma to introduce Cl or F into the gate material 112 in the first region 104 of the workpiece 102, as examples.

Preferably, introducing the substance 115 comprises introducing a relatively small amount of the substance 115 into the gate material 112 in the first region 104. For example, in some embodiments, preferably about 1% or greater of Cl or F is introduced into the gate material 112 in the first region 104, for example. In some embodiments, introducing the substance 115 comprises introducing about 5% or less of Cl or F into the gate material 112 in the first region 104 of the workpiece 102, for example. Alternatively, other percentages of the substance 115 may be introduced into the gate material 112 in the first region 104, for example. The gate material 112a preferably comprises HfSiCl or HfSiF in some embodiments, for example, although alternatively, the gate material 112a may also comprise other materials.

The layer of photoresist 114 over the second region 106 protects the gate material 112b, preventing the substance 115 from affecting the gate material 112b in the second region 106 of the workpiece 102, as shown in FIG. 3. The exposed gate material 112a is altered or affected by the substance 115 in the first region 104 of the workpiece 102.

The layer of photoresist 114 is then removed, as shown in FIG. 4. The workpiece 102 is next subjected to an anneal process 117, also shown in FIG. 4. The anneal process 117 preferably comprises heating the workpiece 102 to a temperature of about 700 degrees C. for about 30 seconds, for example, although other temperatures and lengths of time for the anneal process 117 may also be used. The anneal process 117 may include exposing the workpiece 102 to a nitrogen (N₂) or other environment, such as NH₃, e.g., by introducing a flow of N₂ or other gas to the chamber the semiconductor device 100 is being processed in, while heating the workpiece 102, for example. The anneal process 117 results in a strong bond between the HfSi of the gate material 112 and the substance 115, e.g., a strong bond of HfSi with Cl or HfSi with F, for example.

The gate material 112a in the first region 104 of the workpiece 102 after introducing the substance 115 and after the anneal process 117 preferably comprises a work function that is different from the work function of the gate material 112b in the second region 105 of the workpiece 102. The substance 115 preferably raises the work function value of the gate material 112a in the first region 104, for example, in some embodiments. As an example, in one preferred embodiment, the gate material 112a preferably comprises a work function of about 5.2 eV, and the gate material 112b preferably comprises a work function of about 4.1 eV, although alternatively, the work functions of the gate materials 112a and 112b in the first and second regions 104 and 106 may comprise other values, for example.

Next, optionally, a semiconductive material 116 may be deposited over the gate material 112, as shown in FIG. 5. The semiconductive material 116 comprises part of a gate electrode of the transistors that are later formed in the first region 104 and second region 106 of the workpiece 102, for example. The semiconductive material 116 preferably comprises about 1,000 Angstroms of polysilicon in some embodiments, for example, although alternatively, the semiconductive material 116 may comprise other dimensions and materials. The semiconductive material 116 may comprise a thickness of about 1,500 Angstroms or less, in some embodiments, for example.

Next, the gate materials 116 and 112a/112b and the gate dielectric material 110 are patterned using lithography to form a gate 112a/116 and a gate dielectric 110 of a PMOS transistor 120 in the first region 104 and a gate 112b/116 and a gate dielectric 110 an NMOS transistor 122 in the second region 106, as shown in FIG. 6. For example, a layer of photoresist (not shown) may be deposited over the semiconductive material 116, and the photoresist may be patterned using a lithography mask and an exposure process. The photoresist is developed, and the photoresist is used as a mask while portions of the gate materials 116 and 112a/112b and gate dielectric material 110 are etched away.

The workpiece 102 may be implanted with dopants to form source and drain regions (not shown) proximate the gate dielectric 110. Spacers 118 comprising an insulating material such as an oxide, nitride, or combinations thereof, may be formed over the sidewalls of the gate (112a or 112b)/116 and gate dielectric 110, as shown in FIG. 6.

Processing of the semiconductor device 100 is then continued, such as forming insulating and conductive layers over the transistors 120 and 122, as examples (not shown). For example, one or more insulating materials (not shown) may be deposited over the transistors 120 and 122, and contacts may be formed in the insulating materials in order to make electrical contact with the gate 112/116, and source and/or drain regions. Additional metallization and insulating layers may be formed and patterned over the top surface of the insulating material and contacts. A passivation layer (not shown) may be deposited over the insulating layers or the transistors 120 and 122. Bond pads (also not shown) may be formed over the contacts, and a plurality of the semiconductor devices 100 may then be singulated or separated into individual die. The bond pads may be connected to leads of an integrated circuit package (not shown) or other die, for example, in order to provide electrical contact to the transistors 120 and 122 of the semiconductor device 100.

The transistors 120 and 122 preferably comprise a PMOS transistor 120 and an NMOS transistor 122, in one embodiment. The gate material 112a in the PMOS transistor 120 preferably comprises the substance 115 comprising Cl or F, and the gate material 112b in the NMOS transistor 122 preferably does not comprise the substance 115, in accordance with embodiments of the present invention. The material of the gate material 112 as deposited and substance 115 introduced into the gate material 112a of the PMOS transistor 120 causes the gate material 112a to have a work function of about 5.2 to 5.9 eV, and more preferably to have a work function of about 5.2 eV in some embodiments, as examples. The material of the gate material 112b in the NMOS transistor 122 causes the gate material 112b to have a work function of about 4.0 to 4.2 eV, and more preferably to have a work function of about 4.1 eV, as examples. The transistors 120 and 122 preferably have substantially symmetric threshold voltages of about −0.3 and +0.3 V, respectively, as examples, in one embodiment, although the threshold voltages may alternatively comprise other symmetric threshold voltage levels, such as about ±(0.1 V to about 15 V), as examples. The gate material 112a treated by Cl or F plasma or implanted by Cl or F ions (e.g., substance 115) functions as a p-type metal gate electrode, and the gate material 112b that has not been treated by the substance 115 functions as an n-type metal gate electrode, advantageously.

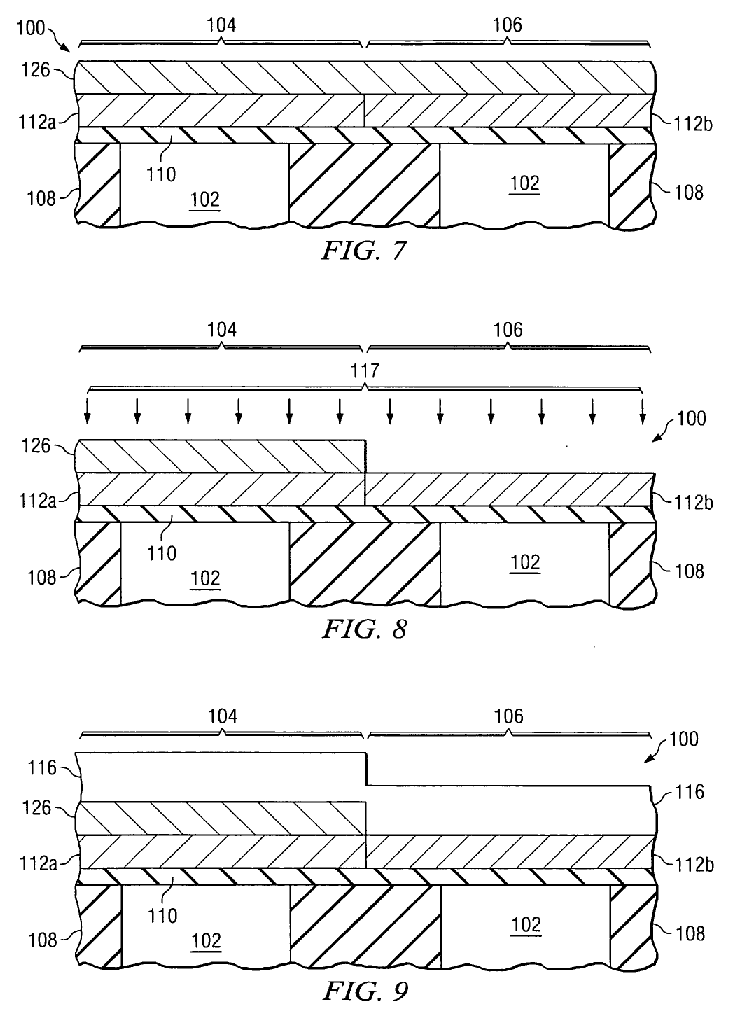

Another preferred embodiment of the present invention is shown in a cross-sectional view in FIGS. 7 through 10 at various stages of manufacturing. Like numerals are used for the elements in FIGS. 7 through 10 as were used in FIGS. 1 through 6, and to avoid repetition, the descriptions of the elements and formation thereof are not repeated herein.

In this embodiment, after introducing the substance 115 into the gate material 112a in the first region 104 of the workpiece and removing photoresist 114 in the second region 106, as shown in FIG. 4, a cap layer 126 is formed over the gate material 112a and 112b in the first and second regions 104 and 106, respectively, as shown in FIG. 7. More preferably, the cap layer 126 is preferably deposited or formed over the gate material 112a and 112b before the anneal process 117 shown in FIG. 4, for example. Alternatively, the cap layer 126 may be deposited or formed after the anneal process 117, for example.

The cap layer 126 preferably comprises a material adapted to incorporate more of the substance 115 into the gate material 112a in the first region 104 of the workpiece 102, for example. For example, the presence of the cap layer 126 causes the incorporation of more of the substance 115 into the gate material 112a of the first region 104 of the workpiece 102 than without the presence of the cap layer 126, e.g., during the anneal process 117. The cap layer 126 preferably comprises TiN in accordance with a preferred embodiment of the present invention, for example, although alternatively, the cap layer 126 may comprise other materials.

In a preferred embodiment, the cap layer 126 comprises a thickness of about 200 Angstroms or less, e.g., about 50 to 100 Angstroms of TiN, although alternatively, the cap layer 126 may comprise other materials and dimensions. The cap layer 126 is preferably deposited by ALD, although other deposition methods may also be used, such as PVD or CVD, as examples. The cap layer 126 functions as a cap to retain the substance 115 comprising Cl or F in the gate material 112a during subsequent processing of the semiconductor device 100, such as the anneal process 117 shown in FIG. 4, for example.

Then, the cap layer 126 is removed from over the gate material 112b in the second region 106, as shown in FIG. 8. The cap layer 126 may be removed from over the second region 106 by depositing a layer of photoresist (not shown) over the cap layer 126, patterning the layer of photoresist using a lithography mask, also not shown, and removing portions of the layer of photoresist from over the second region 106 of the workpiece 102. Portions of the cap layer 126 are removed from over the gate material 112b in the second region 106 using the layer of photoresist as a mask, leaving the cap layer 126 remaining over the gate material 112a in the first region 104 of the workpiece 102, as shown in FIG. 8. The layer of photoresist is then removed.

The workpiece 102 is annealed. The anneal process may comprise an anneal process such as process 117 shown in FIG. 8. For example, the anneal process preferably comprises heating the workpiece 102 to a temperature of about 700 degrees C. for about 30 seconds, for example, although other temperatures and lengths of time for the anneal process 117 may also be used. The anneal process 117 may include exposing the workpiece 102 to a nitrogen (N₂) or other environment, such as NH₃, for example, by introducing a flow of N₂ or other gas to the chamber the semiconductor device 100 is being processed in, while heating the workpiece 102, for example. The anneal process 117 results in a strong bond between the HfSi and the substance, e.g., a strong bond of HfSi with Cl or HfSi with F, for example.

An optional semiconductive material 116 may be formed over the cap layer 126 in the first region 104 and over the gate material 112b in the second region 106, as shown in FIG. 9. Processing of the semiconductor device 100 is then continued as described with reference to FIG. 6, leaving the structure shown in FIG. 10.

Thus, in accordance with embodiments of the present invention, preferably, the gate material 112 as deposited comprises the same material in the first region 104 and the second region 106 of the workpiece 102. The gate material 112a in the first region 104 is altered by introducing a substance 115, wherein the substance alters the work function of the gate material 112a, thus allowing for tuning of the work function of transistors formed in the first region 104 of the workpiece 102.

Referring again to FIG. 5 or 9, note that after depositing the layer of semiconductive material 116, the layer of semiconductive material 116 may be doped using an implantation process with dopants. For example, if the transistor 120 (see FIG. 6) or transistor 130 (see FIG. 10) in the first region 104 comprises a PMOS transistor, the semiconductive material 116 in the first region 104 is preferably implanted with a P type dopant. Alternatively, the semiconductive material 116 in the first region 104 may be implanted with an N type dopant, for example. However, the semiconductive material 116 in the first region 104 may alternatively be implanted with other types of dopants, or may not be doped at all. Likewise, if the transistor 122 (see FIG. 6) or transistor 132 (see FIG. 10) in the second region 106 comprises an NMOS transistor, the semiconductive material 116 in the second region 106 may be implanted with an N type dopant, a P type dopant, another type of dopant, or may not be doped at all, as examples.

Embodiments of the present invention include semiconductor devices 100 that include the novel PMOS transistors 120 and 130 and NMOS transistors 122 and 132, and methods of forming thereof.

FIGS. 11 through 15 are graphs illustrating experimental test results of flat band voltage (V_{fb}) in volts (V) versus the effective oxide thickness (EOT) at various test conditions and device configurations for transistor devices, showing that embodiments of the present invention are effective in achieving a desired work function of transistors. For example, referring next to FIG. 11, a graph of test results of a PMOS transistor 130 (see FIG. 10) fabricated in accordance with an embodiment of the present invention is shown. The PMOS transistor 130 was fabricated by using a gate material 112a comprising HfSi/Cl₂, wherein the Cl₂ 115 was incorporated by a plasma treatment into a gate material 112 comprising HfSi. The PMOS transistor included a TiN cap layer 126 disposed over the gate material 112a. The gate dielectric 110 of the PMOS transistor 130 comprised about 20 Angstroms of HfOₓ. In FIG. 11, the graphs at 134, 136, and 138 show test results in flat band voltage vs. EOT (in nm) for N_{f}, which indicate the fixed charge at the interface between the dielectric film and substrate of about −1.83×10¹¹/cm² and having a work function of about 5.9 eV. Test results for an area of 5×10⁻⁵ cm² are shown at 134, for an area of 2×10⁻⁴ cm² are shown at 136, and for a filtered all-area regression are shown at 138. Thus, the test results show that a gate material 112a comprising HfSi/Cl₂ in accordance with an embodiment of the present invention is effective in increasing the work function of the gate material 112a.

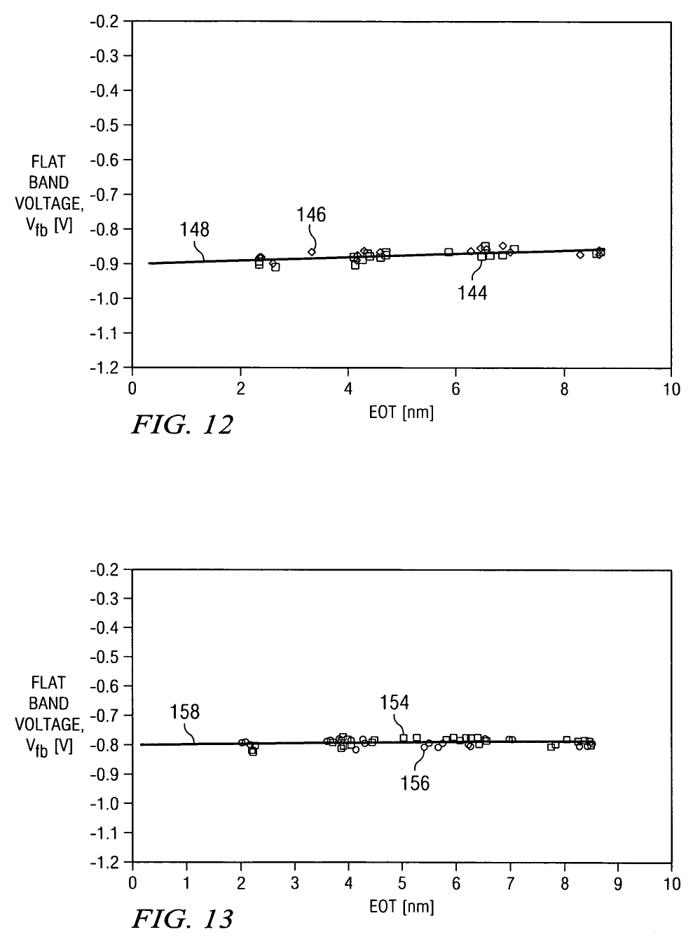

Referring next to FIG. 12, a graph of test results of a NMOS transistor 132 (see FIG. 10) fabricated in accordance with an embodiment of the present invention is shown. The NMOS transistor 132 was fabricated by using a gate material 112b comprising HfSi. The NMOS transistor 132 did not include Cl₂ or a TiN cap layer. The gate dielectric 110 of the NMOS transistor 132 comprised about 20 Angstroms of HfOₓ. In FIG. 12, the graphs at 144, 146, and 148 show test results in flat band voltage vs. EOT (in nm) for N_{f}, which indicate the fixed charge at the interface between the dielectric film and substrate of about −1.07×10¹¹/cm² and having a work function of about 4.17 eV. Test results for an area of 5×10⁻⁵ cm² are shown at 144, for an area of 2×10⁻⁴ cm² are shown at 146, and for a filtered all-area regression are shown at 148. Thus, the test results show that a gate material 112 comprising HfSi in accordance with an embodiment of the present invention is effective in producing a work function of a gate material 112 comprising 4.17 eV.

Referring next to FIG. 13, a graph of test results of a NMOS transistor 132 (see FIG. 10) fabricated in accordance with an embodiment of the present invention is shown. The effect of an anneal for a PMOS transistor 130 on an NMOS transistor 132 is shown. Test results for an area of 5×10⁻⁵ cm² are shown at 154, for an area of 2×10⁻⁴ cm² are shown at 156, and for a filtered all-area regression are shown at 158. The results show that with no anneal on an NMOS transistor 132 having a gate material 112b of HfSi, the flat band voltage vs. EOT (in nm) for N_{f}, was about −1.83×10¹¹/cm² and the work function was about 4.28 eV. The results show that with an anneal process of 700 degrees C. for 30 seconds in a N₂ environment on an NMOS transistor 132 having a gate material 112b of HfSi, the flat band voltage vs. EOT (in nm) for N_{f}, was about −2.84×10¹¹/cm² and the work function was about 4.28 eV. Thus, the test results show that the anneal process used for the PMOS transistor in accordance with an embodiment of the present invention is effective in increasing the work function of the gate material 112a of the PMOS transistor 130 without affecting the work function of the gate material 112b of the NMOS transistor 132.

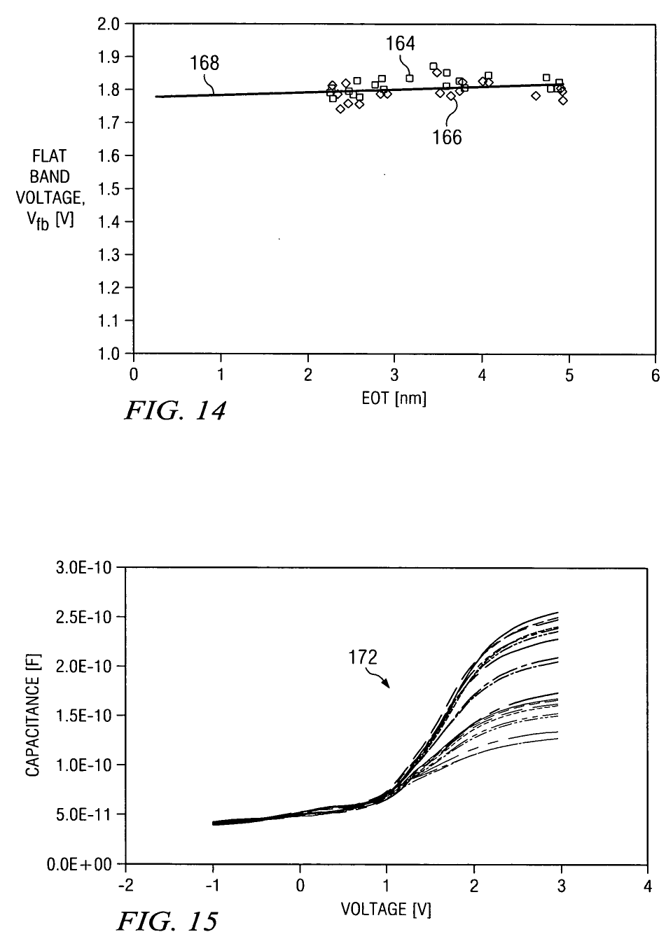

Referring next to FIG. 14, a graph of test results of a PMOS transistor 130 (see FIG. 10) fabricated in accordance with an embodiment of the present invention is shown. The transistor 130 comprises a gate dielectric 110 of HfO₂, a gate material 112a comprising HfSi having a thickness of about 10 nm deposited by CVD and treated using Cl plasma, and including a cap layer 126 of about 5 nm of TiN. Test results for an area of 5×10⁻⁵ cm² are shown at 164, for an area of 2×10⁻⁴ cm² are shown at 166, and for a filtered all-area regression are shown at 168. The results show that the flat band voltage vs. EOT (in nm) for N_{f}, was about −1.83×10¹¹/cm² and the work function was about 5.90 eV. Thus, the test results show that this particular combination of materials 110, 112a, and 126 is effective in increasing the work function of the gate material 112a of a PMOS transistor 130.

Referring next to FIG. 15, a graph 172 of the capacitance vs. voltage for the PMOS transistor 130 described with reference to FIG. 14 is shown. Again, the graph 172 illustrates that this particular combination of materials 110, 112a, and 126 is effective in producing a PMOS transistor 130.

Advantageously, the work function of transistors are established by incorporating a substance 115 into a PMOS transistor and optionally by the use of a cap layer 126 over the top of the gate material 112a of the PMOS transistor, wherein the cap layer 126 assists in retaining more of the substance 115 within the gate material 112a. Note that the expression, “establishes the work function of the transistor” as used herein refers to establishing a work function of the gate electrodes of the transistor, by introducing the substance 115 into the gate material 112a, and by retaining the substance 115 in the gate material 112a using the cap layer 126 during subsequent processing of the semiconductor device 100.

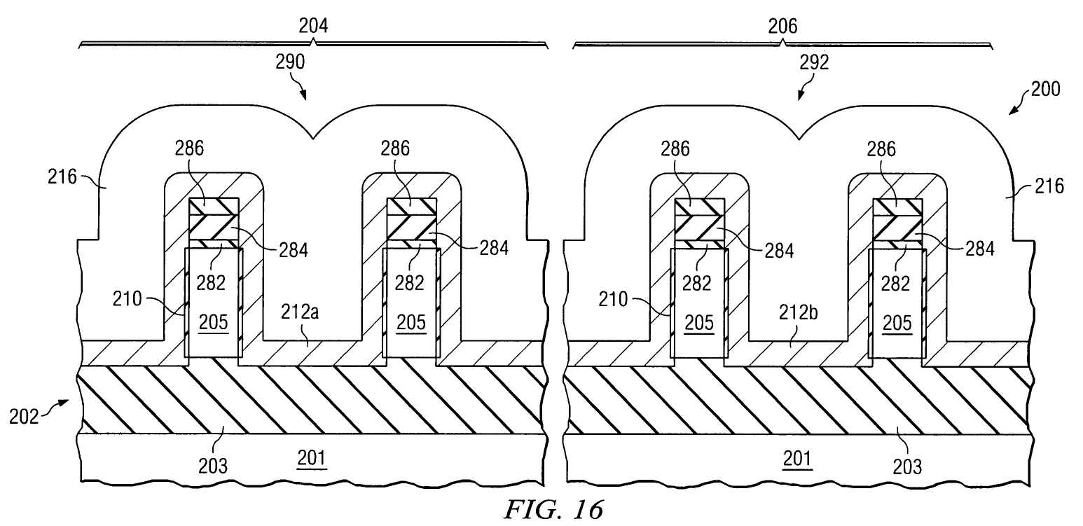

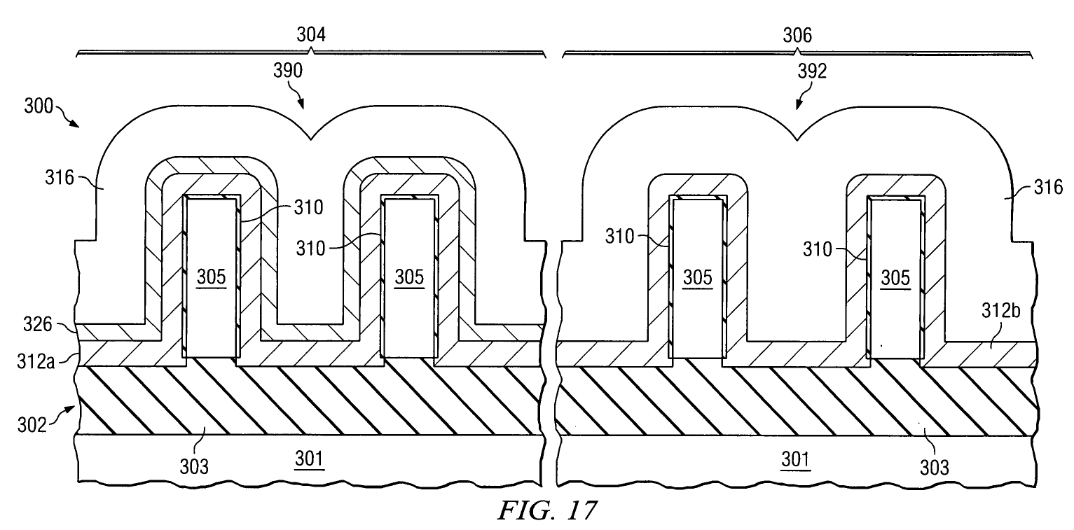

In the embodiments of the invention shown in FIGS. 1 through 6 and 7 through 10, implementation of the present invention in planar transistors having single gate electrodes is shown and described. Embodiments of the present invention may also be implemented in transistors having vertical structures and multiple gates, to be described next with reference to FIGS. 16 and 17.

FIG. 16 shows a cross-sectional view of a semiconductor device 200 in accordance with another preferred embodiment of the present invention, implemented in a FinFET or multiple-gate device. Like numerals are used for the various elements that were described in FIGS. 1 through 6 and 7 through 10. To avoid repetition, each reference number shown in FIG. 10 is not described again in detail herein. Rather, similar materials x02, x04, x06, x08, etc. . . . are preferably used for the various material layers shown as were described for FIGS. 1 through 6 and 7 through 10, where x=1 in FIGS. 1 through 6 and 7 through 10, and x=2 in FIG. 16.

In the embodiment shown in FIG. 16, the semiconductor device 200 comprises a CMOS device comprising at least one multi-gate PMOS transistor 290 and at least one multi-gate NMOS transistor 292, wherein the gate electrode 212a of the PMOS transistor includes the substance 115 comprising Cl or F shown in FIG. 3.

In this embodiment, the workpiece 202 preferably comprises a first layer of semiconductive material 201 that comprises a substrate, a buried insulating layer 203 or buried oxide layer disposed over the first layer of semiconductive material 201, and a second layer of semiconductive material 205 disposed over the buried insulating layer 203, for example. The workpiece 202 may comprise an SOI substrate, for example. The second layer of semiconductor material 205 may comprise silicon (Si) having a thickness of about 100 nm, for example, although alternatively, the second layer of semiconductor material 205 may comprise other materials and dimensions.

To fabricate the semiconductor device 200 shown in FIG. 16, a hard mask 282/284/286 is formed over the workpiece 202. The hard mask 282/284/286 comprises a first oxide layer 282 comprising about 5 nm or less of SiO₂ formed over the workpiece 202. A nitride layer 284 comprising about 20 nm of SiₓN_{y} is formed over the first oxide layer 282. A second oxide layer 286 comprising about 20 nm or less of SiO₂ is formed over the nitride layer 284. Alternatively, the hard mask 282/284/286 may comprise other materials and dimensions, for example.

The semiconductor device 200 includes at least one first region 204 wherein at least one PMOS device will be formed, and at least one second region 206 wherein at least one NMOS device will be formed, as shown. Only one first region 204 and one second region 206 are shown in FIG. 16; however, there may be many first regions 204 and second regions 206 formed on a semiconductor device 200, for example. The first region 204 and the second region 206 may be separated by isolation regions, not shown.

The hard mask 282/284/286 is patterned using lithography, e.g., by depositing a layer of photoresist over the hard mask 282/284/286, exposing the layer of photoresist to energy using a lithography mask, developing the layer of photoresist, and using the layer of photoresist as a mask to pattern the hard mask 282/284/286, for example. The hard mask 282/284/286, and optionally, also the layer of photoresist are used as a mask to pattern the second layer of semiconductive material 205 of the workpiece 202, as shown in FIG. 16. The buried insulating layer 203 may comprise an etch stop layer for the etch process of the second layer of semiconductive material 205, for example. A top portion of the buried insulating layer 203 may be removed during the etch process of the second layer of semiconductive material 201, as shown. For example, the buried insulating layer 203 may have a thickness of about 150 nm, and may be etched by an amount comprising about 15 nm or less, although alternatively, the buried insulating layer 203 may be etched by other amounts.

The second layer of semiconductor material 205 of the workpiece 202 forms vertical fins of semiconductor material 205 extending in a vertical direction away from a horizontal direction of the workpiece 202. The fin structures 205 will function as the channels of PMOS and NMOS devices. The fin structures 205 have a thickness (or height extending away from the buried insulating layer 203) that may comprise about 50 nm or less, as an example, although alternatively, the fins 205 may comprise other dimensions. For example, the thickness of the fin structures 205 may comprise about 5 to 60 nm, or less, in some applications. As another example, the thickness of the fin structures may be larger, such as about 100 to 1,000 nm. The thickness of the fin structures 205 may vary as a function of the channel doping and other dimensions of the fin structures 205, as examples.

The fin structures 205 have a height equivalent to the thickness of the second layer of semiconductor material 205, for example. Only two fin structures 205 are shown in region 204 and region 206 of the semiconductor device 200; however, there may be many fin structures, e.g., about 1 to 200 fin structures, for each PMOS and NMOS device, as examples, although alternatively, other numbers of fin structures 205 may be used.

A gate dielectric material 210 is formed over the sidewalls of the fins of semiconductor material 205, as shown in FIG. 16. The gate dielectric 210 may be formed using a thermal oxidation process, for example, wherein only the semiconductor material 205 is oxidized, as shown. Alternatively, the gate dielectric 210 may be formed using a deposition process, resulting in a thin layer of the gate dielectric 210 also being formed on the buried insulating layer 203 and the hard mask 282/284/286 (not shown), for example. The gate dielectric material 210 preferably comprises similar materials and thicknesses as described for gate dielectric material 110 shown in FIGS. 1 through 10, for example.

Next, a gate material 212 is formed over the fin structures 205 in regions 204 and 206. A substance 215 comprising Cl or F is introduced to the gate material 212a in the first region 204, but not to the gate material 212b in the second region 206. Advantageously, the materials of the gate material 212a and 212b control or establish the work function of the PMOS and NMOS transistors 290 and 292 formed in the first and second regions 204 and 206, respectively.

In region 204, the gate material 212a comprises a first gate electrode on a first sidewall of each fin of semiconductor material 205 and a second gate electrode on a second sidewall of each fin of semiconductor material 205 opposite the first sidewall. Thus, a FinFET having a dual gate electrode structure is formed on each fin of semiconductor material 205. Again, several fins 205 may be placed in parallel to form a PMOS device in the first region 204. In region 206, the gate material 212a comprises a first gate electrode on a first sidewall of each fin 205 and a second gate electrode on a second sidewall of each fin 205 opposing the first sidewall, forming an NMOS device in region 206, for example.

An optional layer of semiconductive material 216 may be formed over the gate material 212a in region 204 and over the gate material 212b in region 206, as shown in FIG. 16. The layer of semiconductive material 216 may comprise polysilicon having a thickness of about 1,000 Angstroms or less, although alternatively, the layer of semiconductive material 216 may comprise other dimensions and materials, for example. The semiconductive material 216 comprises part of a gate electrode of the transistors formed in regions 204 and 206 of the workpiece 202, for example.

The manufacturing process for the semiconductor device 200 is then continued. For example, portions of the gate electrode material may be removed to form the gate electrodes for the CMOS FinFETs, e.g., the gate electrode materials 212a and 212b and optional semiconductor material 216 are simultaneously patterned in region 204 and region 206 to form the gate electrodes of the PMOS and NMOS multiple gate transistors 290 and 292 in region 204 and region 206, respectively. Additional insulating material layers may be formed over the gate electrodes. Contacts may be made to the source, drain, and gate electrodes of the FinFETs, for example, not shown.

Advantageously, a CMOS FinFET device 200 is formed, wherein a multiple gate PMOS transistor 290 in region 204 comprises a gate electrode 212a having a substance 215 incorporated therein that establishes the work function of the PMOS transistors 290. The gate material of the gate electrode 212b also establishes the work function of the NMOS transistors 292 in region 206.

As described with reference to the embodiments in FIGS. 7 through 10, FinFET devices 200 may also be formed wherein a cap layer is also formed in region 204 over the gate material 212a, not shown in FIG. 16. The cap layer facilitates the incorporation of the substance 215 into the gate material 212a of the PMOS transistors 290, for example. Advantageously, by incorporating the substance 215 into the gate material 212a of the PMOS transistor 290 and by the optional use of the cap layer, and by selection of the material of the gate material 212b of the NMOS transistors 292, the work function of the transistors 290 and 292 may be tuned in accordance with embodiments of the present invention, so that a symmetric threshold voltage of the PMOS transistors 290 and NMOS transistors 292 may be achieved.

FIG. 17 shows a cross-sectional view of an embodiment of the present invention implemented in a multiple gate device having three gates for each transistor. Like numerals are used for the elements in FIG. 17 as were used in FIG. 16 and the other figures. In this embodiment, a hard mask is not used over the top surface of the second layer of semiconductor material 305 of the SOI substrate 302, or alternatively, the hard mask is removed after the second layer of semiconductor material 305 is patterned to form the fin structures 305. In this embodiment, each transistor includes three first gate electrodes on a fin structure 305. A first gate electrode is disposed on a first sidewall of the fin structures 305, and a second gate electrode is disposed on a second sidewall of the fin structures 305, wherein the second sidewall opposes the first sidewall of the same fin structure 305. A third gate electrode is disposed on a top surface of each fin structure 305. The fin structures 305 function as channels of the transistors in regions 304 and 306, for example.

Transistors 390 comprise gate electrodes comprised of the gate material 312a, cap layer 326, and semiconductive material layer 316. The materials of the gate materials 312a and cap layer 326 establish the work function of the transistors 390 in region 304. Transistors 392 comprise gate electrodes comprised of the gate material 312b and semiconductive material layer 316. The material of the gate material 312b establishes the work function of the transistors 392 in region 306.

Processing of the semiconductor device is then continued. For example, portions of the fin structures 305 may be implanted with dopants to form source and drain regions. The implantation steps to form the source and drain regions may alternatively take place before the manufacturing process steps described herein, in some embodiments, for example. After patterning the material layers 316, 326, and 312a/312b to form the gate electrodes of the transistors 390 and 392, spacers comprising an insulating material such as an oxide, nitride, or combinations thereof, may be formed over the sidewalls of the gate electrodes (and hard mask 282, 284, 286, if included, shown in FIG. 16).

In some embodiments, the gate material 112a, 212a, and 312a and optional cap layer 126 and 326 described herein cause the gate material of PMOS transistors 120, 130, 290, and 390 to have a work function of about 5.2 to 5.9 eV, and the gate material 112b, 212b, and 312b causes the gate material of the NMOS transistors 122, 132, 292, and 392 to have a work function of about 4.1 to 4.3 eV. The PMOS transistors 120, 130, 290, and 390 and the NMOS transistors 122, 132, 292, and 392 preferably have substantially symmetric threshold voltages of about +0.3 and −0.3 V, respectively, as an example, in one embodiment, although the threshold voltages may alternatively comprise other voltage levels, such as symmetric threshold voltages Vₜ values of about ±(0.1 V to 15 V), as examples.

Embodiments of the present invention achieve technical advantages in several different device applications. For example, embodiments of the invention may be implemented in NMOS high performance (HP) devices, NMOS low operation power (LOP) devices, NMOS Low Standby Power (LSTP) devices, PMOS high performance devices, PMOS low operation power devices, and PMOS Low Standby Power devices, as examples. The parameters for these HP devices, LOP devices, and LSTP devices, are defined in the 2002 edition of International Technology Roadmap for Semiconductors (ITRS), which is incorporated herein by reference. Preferably, in accordance with embodiments of the present invention, all devices of one type (e.g., either NMOS or PMOS) will have the same implantation doping levels, e.g., for forming source and drain regions of transistors, but may comprise different gate electrode materials, and may or may not have cap layers disposed over the PMOS transistors, according to the type of device, e.g., HP, LOP, or LSTP. Additional implantation processes for the source and drain regions may be optional, but are not necessary, for example.

In one embodiment, a first transistor may comprise a first CMOS device, and a second transistor may comprise a second CMOS device, wherein the first CMOS device comprises a first device type, and wherein the second CMOS device comprises a second device type. The second device type is preferably different from the first device type. For example, the first device type and/or the second device type may comprise a high performance (HP) device, a low operation power (LOP) device, or a low standby power (LSTP) device, for example.

Thus, novel semiconductor devices 100, 200, and 300 comprising CMOS devices having PMOS and NMOS devices comprising different gate electrode materials are formed in accordance with embodiments of the present invention. Advantages of preferred embodiments of the present invention include providing methods of fabricating semiconductor devices 100, 200, and 300 and structures thereof. The PMOS and NMOS transistors have a substantially symmetric threshold voltage Vₜ. For example, Vₜₚ is preferably about −0.3 V, and Vₜₘ may be the substantially the same positive value, e.g., about +0.3 V. The novel introduction of Cl or F to the PMOS transistor gate material may be used to tune and adjust the work function of the gates of transistors to achieve a desired threshold voltage, such as a symmetric threshold voltage for PMOS and NMOS transistors in a CMOS device, for example, or to provide a single PMOS transistor having a work function tuned to about 5.2 to 5.9 eV. The gate electrode material of the NMOS transistor, the Cl or F introduced to the PMOS transistor, and also the optional cap layer 126, 326 set the work function of the gate electrodes of the NMOS and PMOS transistors, for example.

Although embodiments of the present invention and their advantages have been described in detail, it should be understood that various changes, substitutions and alterations can be made herein without departing from the spirit and scope of the invention as defined by the appended claims. For example, it will be readily understood by those skilled in the art that many of the features, functions, processes, and materials described herein may be varied while remaining within the scope of the present invention. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of manufacturing a semiconductor device, the method comprising:
providing a workpiece;
disposing a gate dielectric material over the workpiece;
disposing a gate material over the gate dielectric material;
introducing Cl or F to the gate material, wherein introducing the Cl or F to the gate material affects a work function of the gate material; and
patterning the gate material and the gate dielectric material, forming at least one transistor.

2. The method according to claim 1, further comprising disposing a cap layer over the gate material, before patterning the gate material and the gate dielectric material, wherein the cap layer affects the work function of the gate material.

3. The method according to claim 1, wherein the transistor comprises a positive channel metal oxide semiconductor (PMOS) transistor.

4. The method according to claim 1, further comprising annealing the workpiece, after introducing Cl or F to the gate material.

5. The method according to claim 4, wherein annealing the workpiece comprises annealing the workpiece in a N₂ or NH₃ environment at a temperature of about 700 degrees C.

6. A semiconductor device, comprising:
a workpiece;
a gate dielectric material disposed over the workpiece;
a gate material disposed over the gate dielectric material, the gate material comprising about 5% or less of Cl or F, wherein the gate material and the gate dielectric material comprise at least one transistor.

7. The semiconductor device according to claim 6, wherein the gate material comprises HfSi.

8. The semiconductor device according to claim 6, wherein the gate material comprises a thickness of about 200 Angstroms or less.

9. The semiconductor device according to claim 6, wherein the gate dielectric material comprises a material having a dielectric constant of about 4.0 or greater.

10. The semiconductor device according to claim 6, wherein the gate dielectric material comprises a hafnium-based dielectric, HfO₂, HfSiOₓ, Al₂O₃, ZrO₂, ZrSiOₓ, Ta₂O₅, La₂O₃, nitrides thereof, SiₓN_{y}, SiON, HfAlOₓ, HfAlOₓN_{1-x-y}, ZrAlOₓ, ZrAlOₓN_{y}, SiAlOₓ, SiAlOₓN_{1-x-y}, HfSiAlOₓ, HfSiAlOₓN_{y}, ZrSiAlOₓ, ZrSiAlOₓN_{y}, SiO₂, combinations thereof, or multiple layers thereof.

11. A method of manufacturing a semiconductor device, the method comprising:
providing a workpiece, the workpiece having a first region and a second region;
forming a gate dielectric material over the workpiece;
forming a gate material over the gate dielectric material;
introducing Cl or F to the gate material in the first region of the workpiece;
annealing the workpiece; and
patterning the gate material and the gate dielectric material to form at least one first transistor in the first region and at least one second transistor in the second region.

12. The method according to claim 11, wherein introducing the Cl or F to the gate material in the first region comprises implanting the Cl or F or treating the gate material with Cl or F plasma.

13. The method according to claim 11, further comprising masking the second region, before introducing the Cl or F to the gate material in the first region of the workpiece.

14. The method according to claim 11, further comprising forming a cap layer over the gate material in the first region, and wherein patterning the gate material and the gate dielectric material further comprises patterning the cap layer.

15. The method according to claim 14, wherein forming the cap layer comprises forming a layer of TiN having a thickness of about 200 Angstroms or less.

16. The method according to claim 11, wherein forming the gate material comprises forming about 200 Angstroms or less of HfSi.

17. The method according to claim 11, wherein forming the at least one first transistor comprises forming a first CMOS device, wherein forming the at least one second transistor comprises forming a second CMOS device, wherein the first CMOS device comprises a first device type, wherein the second CMOS device comprises a second device type, wherein the second device type is different from the first device type, and wherein the first device type and the second device type comprise a high performance (HP) device, a low operation power (LOP) device, or a low standby power (LSTP) device.

18. The method according to claim 11, wherein providing the workpiece comprises providing a silicon-on-insulator (SOI) substrate having a substrate, a buried insulating layer disposed over the substrate, and a layer of semiconductor material disposed over the buried insulating layer, further comprising, before forming the gate dielectric material over the workpiece:
forming at least one first fin structure and at least one second fin structure within the layer of semiconductor material disposed over the buried insulating layer of the SOI substrate within the first region and second region of the workpiece, respectively, each of the at least one first fin structure and each of the at least one second fin structure comprising a first sidewall and an opposing second sidewall, wherein forming the gate dielectric material comprises forming the gate dielectric material over at least the first and second sidewalls of the at least one first fin structure and the at least one second fin structure, wherein patterning the gate material and the gate dielectric material comprise forming at least two first gate electrodes in the first region and forming at least two second gate electrodes in the second region, wherein the at least two first gate electrodes, the gate dielectric material, and the at least one first fin structure comprise the at least one first transistor, and wherein the at least two second gate electrodes, the gate dielectric material, and the at least one second fin structure comprise the at least one second transistor.

19. The method according to claim 18, wherein patterning the gate material and the gate dielectric material comprise forming a plurality of first transistors in the first region and a plurality of second transistors in the second region.

20. A semiconductor device, comprising:
a positive channel metal oxide semiconductor (PMOS) transistor, the PMOS transistor comprising at least one first gate electrode including a gate material and about 1% or greater of Cl or F; and
a negative channel metal oxide semiconductor (NMOS) transistor, the NMOS transistor comprising at least one second gate electrode including the gate material.

21. The semiconductor device according to claim 20, wherein the at least one first gate electrode of the PMOS transistor comprises a work function of about 5.2 to 5.9 eV, and wherein the at least one second gate electrode of the NMOS transistor comprises a work function of about 4.0 to 4.2 eV.

22. The semiconductor device according to claim 20, wherein the PMOS transistor and the NMOS transistor comprise symmetric threshold voltage Vₜ values of about ±(0.1 V to 15) V.

23. The semiconductor device according to claim 20, further comprising a layer of semiconductive material disposed over the at least one first gate electrode and the at least one second gate electrode.

24. The semiconductor device according to claim 23, wherein the layer of semiconductive material comprises about 1,500 Angstroms or less of polysilicon.

25. The semiconductor device according to claim 23, wherein the layer of semiconductive material is implanted with a dopant.

26. The semiconductor device according to claim 20, wherein the PMOS transistor comprises a single gate electrode or multiple gate electrodes, and wherein the NMOS transistor comprises a single gate electrode or multiple gate electrodes.
